(19) United States
(12) Patent Application Publication
(10) Pub. No.: US 2026/0006903 A1
(43) Pub. Date: Jan. 1, 2026

(54) SEMICONDUCTOR STRUCTURE AND MANUFACTURING METHOD THEREOF

(71) Applicant: United Microelectronics Corp., Hsinchu (TW)

(72) Inventor: Shin-Hung Li, Nantou County (TW)

(73) Assignee: United Microelectronics Corp., Hsinchu (TW)

(21) Appl. No.: 18/793,966

(22) Filed: Aug. 5, 2024

(30) Foreign Application Priority Data
Jul. 1, 2024 (TW) 113124564

(51) Int. Cl. H01L 27/088; H01L 21/8234

(52) U.S. Cl. CPC H10D 84/834; H10D 84/0151; H10D 84/0158; H10D 84/038

(57) ABSTRACT

Provided are a semiconductor structure and a manufacturing method thereof. The semiconductor structure includes a substrate, first and second isolation structures, first, second and third gates, first, second and third gate insulating layers, a drift region, and source/drain regions. The substrate in the first region includes fins. The first isolation structure surrounds the fins and exposes a part of each fin. The second isolation structure is disposed in the substrate in the second region. The first gate is disposed on the exposed portions of the fins. The second gate is disposed on the substrate in the second region and on a portion of the second isolation structure. The second gate insulating layer is disposed between the second gate and the substrate. The drift region is disposed in the substrate on a side of the second isolation structure away from the second gate, and extends below the second isolation structure.

### CROSS-REFERENCE TO RELATED APPLICATION

This application claims the priority benefit of Taiwan application serial no. 113124564, filed on Jul. 1, 2024. The entirety of the above-mentioned patent application is hereby incorporated by reference herein and made a part of this specification.

### BACKGROUND

### Technical Field

The present invention relates to a semiconductor structure and a manufacturing method thereof, and in particular to a semiconductor structure including a high-voltage (HV) device, a low-voltage (LV) device and a transistor for a level shifter circuit and a manufacturing method thereof.

### Description of Related Art

In the semiconductor apparatus, the level shifter circuit is used to convert a low voltage from the low-voltage device to a high voltage and output the high voltage to a high-voltage device.

Generally speaking, the level shifter circuit may include the extend-drain metal oxide semiconductor (EDMOS) transistor. In the EDMOS transistor, the gate insulating layer adjacent to the source has a smaller thickness, while the gate insulating layer adjacent to the drain has a larger thickness to withstand a higher voltage. Since the gate insulating layer below the gate has uneven thickness, the process of the EDMOS transistor is more complicated.

### SUMMARY

The present invention provides a semiconductor structure and a manufacturing method thereof, wherein the isolation structure may be used as a portion of the gate insulating layer of the EDMOS transistor.

The semiconductor structure of the present invention includes a substrate, a first isolation structure, a second isolation structure, a first gate, a first gate insulating layer, a second gate, a second gate insulating layer, a drift region, a third gate, a third gate insulating layer, and source/drain regions. The substrate has a first region, a second region and a third region, wherein the substrate in the first region comprises a plurality of fin portions. The first isolation structure is disposed around the plurality of fin portions and exposing a portion of each of the plurality of fin portions. The second isolation structure is disposed in the substrate in the second region. The first gate is disposed on the exposed portions of the plurality of fin portions. The first gate insulating layer is disposed between the first gate and the plurality of fin portions. The second gate is disposed on the substrate in the second region and on a portion of the second isolation structure. The second gate insulating layer is disposed between the second gate and the substrate. The drift region is disposed in the substrate on a side of the second isolation structure away from the second gate, and extending below the second isolation structure. The third gate is disposed on the substrate in the third region. The third gate insulating layer is disposed between the third gate and the substrate. The source/drain regions are disposed at the fin portions on both sides of the first gate in an extending direction of each of the plurality of fin portions, in the substrate on both sides of the second gate and in the substrate on both sides of the third gate.

In an embodiment of the semiconductor structure of the present invention, a top surface of the second isolation structure is lower than a top surface of the first isolation structure.

In an embodiment of the semiconductor structure of the present invention, a top surface of the second isolation structure is lower than a top surface of the substrate in the second region.

In an embodiment of the semiconductor structure of the present invention, the second isolation structure has an extension portion on the side away from the second gate, a top surface of the extension portion is coplanar with the top surface of the substrate in the second region, and the extension portion is separated from the second gate.

In an embodiment of the semiconductor structure of the present invention, a bottom surface of the second isolation structure is coplanar with a bottom surface of the first isolation structure.

In an embodiment of the semiconductor structure of the present invention, a distance between a sidewall of the second gate located on the second isolation structure and the substrate on the side of the second isolation structure away from the second gate is greater than a thickness of the second isolation structure below the second gate.

In an embodiment of the semiconductor structure of the present invention, the source/drain region in the second region is located in the drift region.

In an embodiment of the semiconductor structure of the present invention, a top surface of the substrate in the third region is lower than a top surface of each of the plurality of fin portions.

In an embodiment of the semiconductor structure of the present invention, a boundary of an end of the drift region below the second isolation structure is aligned with a sidewall of the second isolation structure.

The manufacturing method of a semiconductor structure of the present invention includes the following steps. A substrate is provided, wherein the substrate has a first region, a second region and a third region, and the substrate in the first region comprises a plurality of fin portions. A first isolation structure is formed around the plurality of fin portions, wherein the first isolation structure exposes a portion of each of the plurality of fin portions. A second isolation structure is formed in the substrate in the second region. A first gate is formed on the exposed portions of the plurality of fin portions. A first gate insulating layer is formed between the first gate and the plurality of fin portions. A second gate is formed on the substrate in the second region and on a portion of the second isolation structure. A second gate insulating layer is formed between the second gate and the substrate. A drift region is formed in the substrate on a side of the second isolation structure away from the second gate, wherein the drift region extends below the second isolation structure. A third gate is formed on the substrate in the third region. A third gate insulating layer is formed between the third gate and the substrate. Source/drain regions are formed at the fin portions on both sides of the first gate in an extending direction of each of the plurality of fin portions, in the substrate on both sides of the second gate and in the substrate on both sides of the third gate.

In an embodiment of the manufacturing method of the semiconductor structure of the present invention, a forming method of the plurality of fin portions, the first isolation structure and the second isolation structure includes the following steps. A first initial isolation structure is formed in the substrate in the first region to define the plurality of fin portions. A second initial isolation structure is formed in the substrate in the second region. A part of the second initial isolation structure is removed, so that a top surface of the second initial isolation structure is lower than a top surface of the first initial isolation structure. A part of the first initial isolation structure is removed to form the first isolation structure. A part of the second initial isolation structure is removed to form the second isolation structure.

In an embodiment of the manufacturing method of the semiconductor structure of the present invention, a part of the substrate in the third region is further removed before forming the first initial isolation structure and the second initial structure isolation, so that a top surface of the substrate in the third region is lower than top surfaces of remaining parts of the substrate.

In an embodiment of the manufacturing method of the semiconductor structure of the present invention, a bottom surface of the second initial isolation structure is coplanar with a bottom surface of the first initial isolation structure.

In an embodiment of the manufacturing method of the semiconductor structure of the present invention, the drift region is formed in the substrate on a side of the second initial isolation structure after forming the first initial isolation structure and the second initial isolation structure and before removing the part of the second initial isolation structure so that the top surface of the second initial isolation structure is lower than the top surface of the first initial isolation structure.

In an embodiment of the manufacturing method of the semiconductor structure of the present invention, the third gate insulating layer is formed on the substrate in the third region after removing the part of the second initial isolation structure so that the top surface of the second initial isolation structure is lower than the top surface of the first initial isolation structure and before removing the part of the first initial isolation structure.

In an embodiment of the manufacturing method of the semiconductor structure of the present invention, the first gate, the first gate insulating layer, the second gate, the second gate insulating layer and the third gate are formed after removing the part of the second initial isolation structure to form the second isolation structure.

In an embodiment of the manufacturing method of the semiconductor structure of the present invention, the source/drain regions are formed after forming the first gate, the second gate and the third gate.

In an embodiment of the manufacturing method of the semiconductor structure of the present invention, the second isolation structure has an extension portion on the side away from the second gate, a top surface of the extension portion is coplanar with a top surface of the substrate in the second region, and the extension portion is separated from the second gate.

In an embodiment of the manufacturing method of the semiconductor structure of the present invention, a distance between a sidewall of the second gate located on the second isolation structure and the substrate on the side of the second isolation structure away from the second gate is greater than a thickness of the second isolation structure below the second gate.

In an embodiment of the manufacturing method of the semiconductor structure of the present invention, a boundary of an end of the drift region below the second isolation structure is aligned with a sidewall of the second isolation structure.

Based on the above, in the semiconductor structure and the manufacturing method thereof of the present invention, the isolation structure may be used as a portion of the gate insulating layer of the EDMOS transistor. Therefore, there is no need to perform additional processes to form gate insulating layers with different thicknesses.

In addition, in the semiconductor structure of the present invention, the gate of the EDMOS transistor is disposed on the substrate and on a portion of the isolation structure, and the distance between the sidewall of the gate on the isolation structure and the substrate is greater than the thickness of the isolation structure below the gate as the gate insulating layer, the short circuit caused by too small distance between the gate and the substrate may be effectively avoid.

In addition, in the manufacturing method of the semiconductor structure of the present invention, the process of the transistor used in the level shifter circuit is integrated with the process of the fin field effect transistor (FinFET), thus the process steps may be effectively simplified.

### BRIEF DESCRIPTION OF THE DRAWINGS

FIGS. 1A to 1G are schematic cross-sectional views of the manufacturing process of the semiconductor structure of the present invention embodiment.

### DESCRIPTION OF THE EMBODIMENTS

The embodiments are listed below and described in detail with the accompanying drawings, but the provided embodiments are not intended to limit the scope of the present invention. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention. Therefore, it should be understood that “on” may be used interchangeably with “under”. When a device such as a layer or a film is placed “on” another device, the device may be placed directly on the other device, or an intermediate device may be present. On the other hand, when a device is placed “directly on” another device, there is no intermediate device between the two.

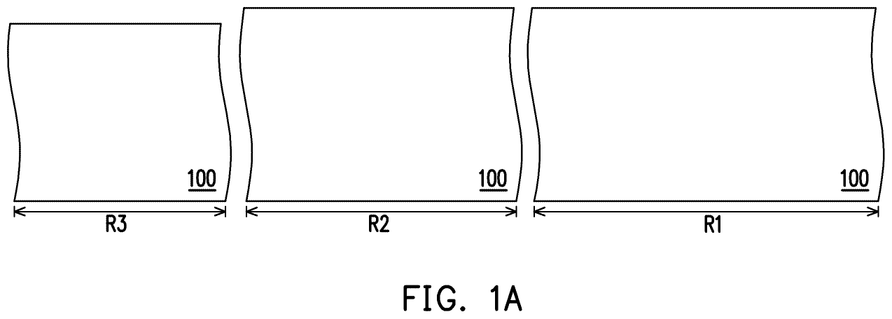

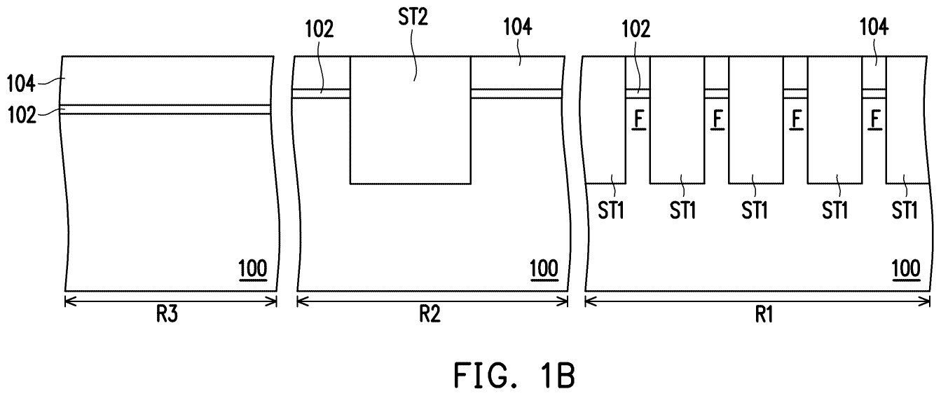

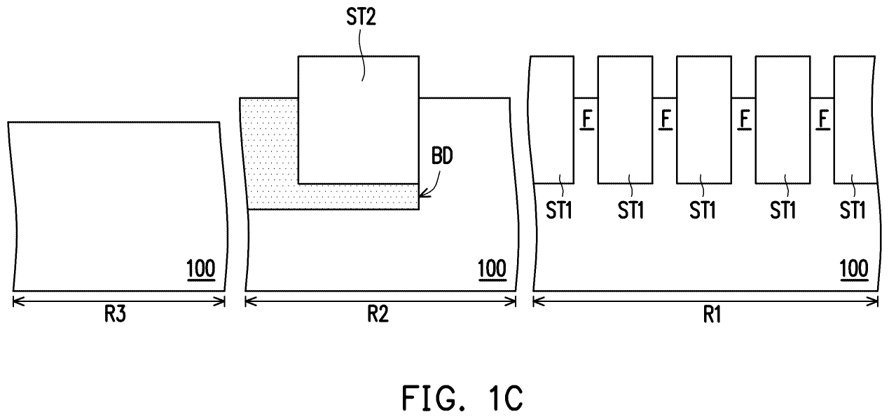

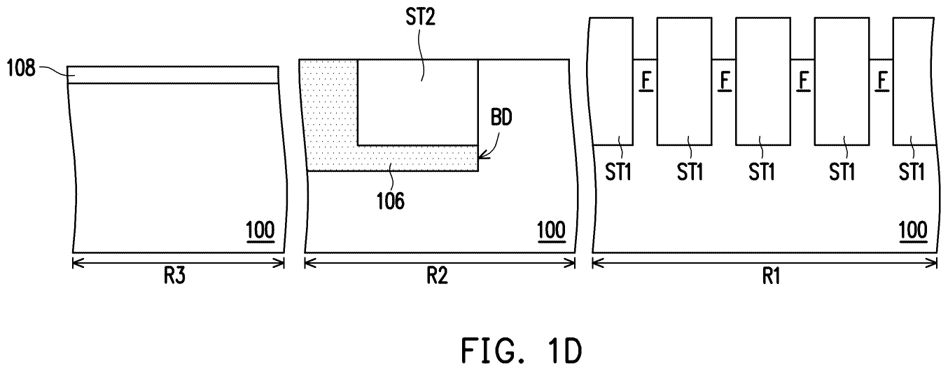

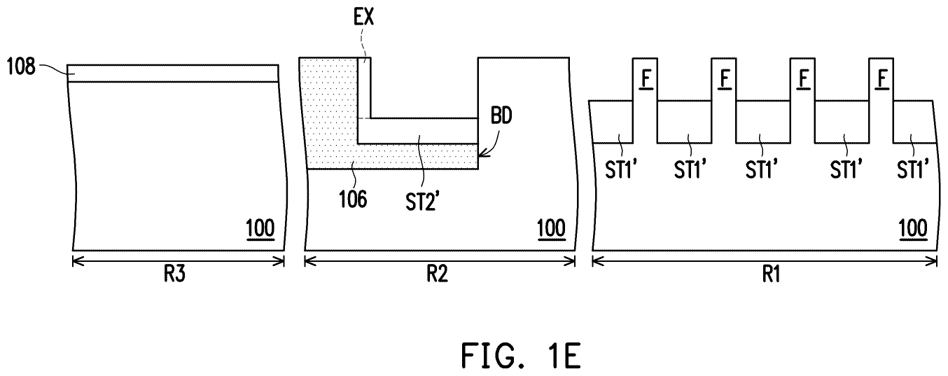

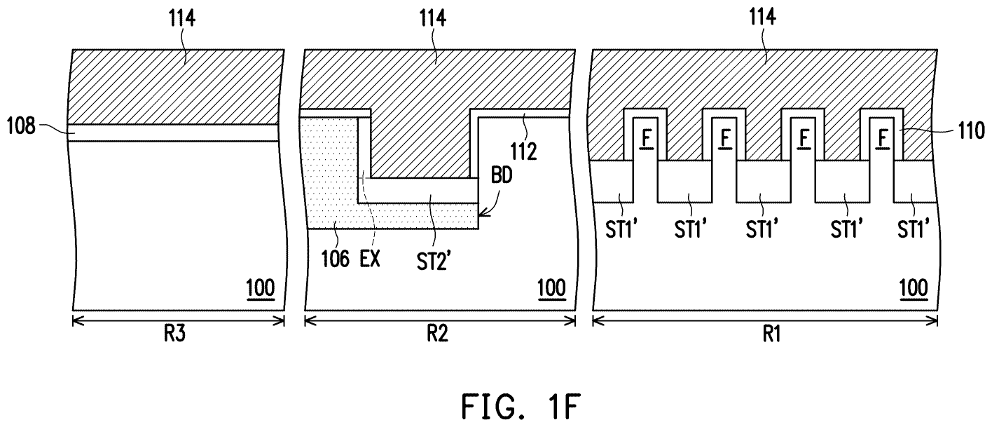

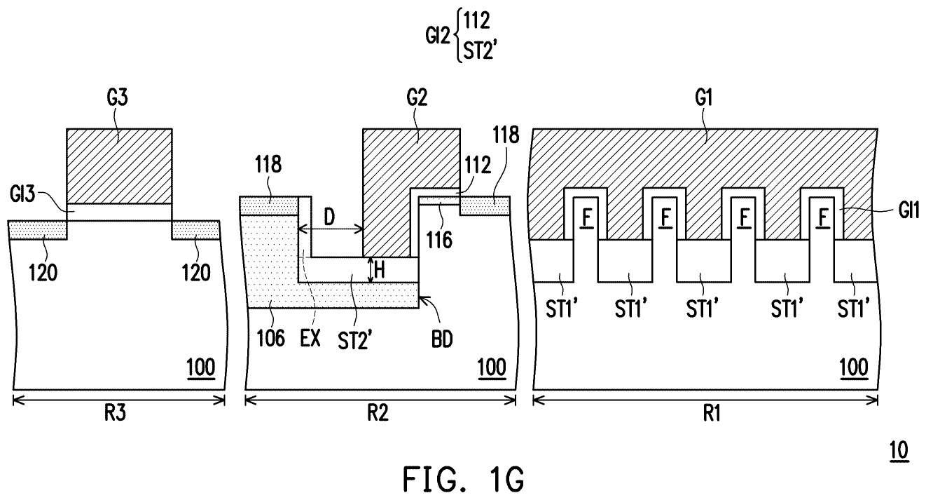

FIGS. 1A to 1G are schematic cross-sectional views of the manufacturing process of the semiconductor structure of the present invention embodiment.

Referring to FIG. 1A, a substrate 100 is provided. In the present embodiment, the substrate 100 may be a silicon substrate. The substrate 100 has a first region R1, a second region R2 and a third region R3. In the present embodiment, the first region R1, the second region R2 and the third region R3 may be located at any desired position of the substrate 100, which is not limited by the present invention.

In the present embodiment, the first region R1 is a region where the relatively low-voltage device is to be formed, the third region R3 is a region where the relatively high-voltage device is to be formed, and the second region R2 is a region where the level shifter circuit is to be formed. For example, the FinFET may be formed in the first region R1, the EEDMOS transistor may be formed in the second region R2, and the high-voltage transistor may be formed in the third region R3.

After that, a part of the substrate 100 in the third region R3 is removed, so that the top surface of the substrate 100 in the third region R3 is lower than the top surfaces of the remaining parts of the substrate 100. In the present embodiment, the third region R3 is a region where the relatively high-voltage device is to be formed. Therefore, making the top surface of the substrate 100 in the third region R3 lower than the top surfaces of the remaining parts of the substrate 100 may avoid the obvious height difference between the top surface of the gate subsequently formed in the third region R3 and the top surface of the gate formed in other regions due to the thicker thickness of the gate insulating layer in the third region R3.

Referring to FIG. 1B, a pad layer 102 and a hardmask layer 104 may be sequentially formed on the substrate 100. In the present embodiment, the material of the pad layer 102 is, for example, silicon oxide, and the material of the hardmask layer 104 is, for example, silicon nitride, but the present invention is not limited thereto. Afterwards, a first initial isolation structure ST1 is formed in the pad layer 102, the hardmask layer 104 and the substrate 100 in the first region R1, and a second initial isolation structure ST2 is formed in the pad layer 102, the hardmask layer 104 and the substrate 100 in the second region R2. In the present embodiment, the size of the first initial isolation structure ST1 is smaller than the size of the second initial isolation structure ST2.

In the present embodiment, the first initial isolation structure ST1 and the second initial isolation structure ST2 may be formed at the same time, so the bottom surface of the first initial isolation structure ST1 and the bottom surface of the second initial isolation structure ST2 may be coplanar, but the present invention is not limited thereto. In addition, a desired isolation structure (not shown) may be formed in the third region R3, and the bottom surface of the isolation structure in the third region R3 may be located at a desired depth in the substrate 100. For example, the bottom surface of the isolation structure in the third region R3 may be lower than the bottom surfaces of the first initial isolation structure ST1 and the second initial isolation structure ST2, or the bottom surface of the isolation structure in the third region R3 may be coplanar with the bottom surfaces of the first initial isolation structure ST1 and the second initial isolation structure ST2. The forming method of the first initial isolation structure ST1, the second initial isolation structure ST2 and the isolation structure in the third region R3 are well known to those skilled in the art and will not be described further here.

In addition, after the first initial isolation structure ST1 is formed, the substrate 100 in the first region R1 is defined to include a plurality of fin portion F. The first initial isolation structure ST1 is located around the fin portion F. In FIG. 1B, the number and size of the fin portions F are only exemplary, and the present invention does not limit this.

Referring to FIG. 1C, the pad layer 102 and the hardmask layer 104 are removed. After that, a drift region 106 may be formed in the substrate 100 on one side of the second initial isolation structure ST2. The forming method of the drift region 106 may include the following steps. First, an ion implantation process may be performed to implant the dopant into the substrate 100 on one side of the second initial isolation structure ST2. After that, a heat treatment may be performed to diffuse the dopant into the substrate 100 below the second initial isolation structure ST2.

In the present embodiment, through the heat treatment, the formed drift region 106 may extend below the second initial isolation structure ST2, and a boundary BD of the end of the extension portion of the drift region 106 may be aligned with the sidewall of the second initial isolation structure ST2, but the present invention is not limited thereto. In other embodiments, the boundary BD of the end of the drift region 106 extending below the second initial isolation structure ST2 may not be aligned with the sidewall of the second initial isolation structure ST2, as long as the boundary BD is located below the second initial isolation structure ST2 and as close as possible to the side wall of the second initial isolation structure ST2.

In addition, during forming the drift region 106, a well region and/or a lightly doped drain (LDD) region (not shown) may be formed simultaneously in the substrate 100 in the third region R3.

Referring to FIG. 1D, a part of the second initial isolation structure ST2 is removed, so that the top surface of the second initial isolation structure ST2 is lower than the top surface of the first initial isolation structure ST1. After that, a dielectric layer 108 is formed on the substrate 100 in the third region R3. The material of the dielectric layer 108 is, for example, silicon oxide. The dielectric layer 108 is used to form the gate insulating layer of the high-voltage transistor in the third region R3. The forming method of the dielectric layer 108 is well known to those skilled in the art and will not be described further here.

Referring to FIG. 1E, a part of the first initial isolation structure ST1 is removed to form a first isolation structure ST1′. The method for removing a part of the first initial isolation structure ST1 is, for example, to perform an etching-back process. The top surface of the formed first isolation structure ST1′ is lower than the top surfaces of the fin portions F, and the formed first isolation structure ST1′ surrounds the fin portions F and exposes the upper portions of the fin portions F.

In addition, in one embodiment, during removing the part of the first initial isolation structure ST1, a part of the second initial isolation structure ST2 may be removed simultaneously to form a second isolation structure ST2′. The top surface of the formed second isolation structure ST2′ is lower than the top surface of the first isolation structure ST1′. Alternatively, in another embodiment, after forming the first isolation structure ST1′, a part of the second initial isolation structure ST2 may be removed to form the second isolation structure ST2′. Therefore, the top surface of the second isolation structure ST2′ is lower than the top surface of the first isolation structure ST1′ and the top surface of the substrate 100 in the second region R2. In this way, the second isolation structure ST2′ may have a smaller thickness to serve as a portion of the gate insulating layer of the EDMOS transistor in the second region R2.

In the present embodiment, after the part of the second initial structure isolation ST2 is removed, the formed second isolation structure ST2′ has an extension portion EX. In detail, during removing the part of the second initial isolation structure ST2, a portion of the second initial isolation structure ST2 adjacent to the drift region 106 is remained to form the extension portion EX. The extension portion EX extends upward from the top surface of the second isolation structure ST2′, so that the top surface of the extension portion EX is coplanar with the top surface of the substrate 100 in the second region R2. In another embodiment, the extension portion EX may not be formed during removing the part of the second initial structure isolation ST2.

Referring to FIG. 1F, a dielectric layer 110 is formed on the exposed surfaces of the fin portions F in the first region R1, and a dielectric layer 112 is formed on the substrate 100 in the second region R2. The material of the dielectric layer 110 and the dielectric layer 112 is, for example, silicon oxide. The dielectric layer 110 is used to form the gate insulating layer of the FinFET in the first region R1, and the dielectric layer 112 is used to form a portion of the gate insulating layer of the EDMOS transistor in the second region R2. The thickness of dielectric layer 110 and the thickness of the dielectric layer 112 are less than the thickness of dielectric layer 108.

After the dielectric layer 110 and the dielectric layer 112 are formed, a conductive layer 114 is formed on the substrate 100. The material of the conductive layer 114 is polysilicon, for example. The conductive layer 114 is used to form the gates of the transistors in the first region R1, the second region R2 and the third region R3. The forming methods of the dielectric layer 110, the dielectric layer 112 and the conductive layer 114 are well known to those skilled in the art and will not be described further here.

Referring to FIG. 1G, a patterning process may be performed on the conductive layer 114 and the dielectric layer 108, the dielectric layer 110 and dielectric layer 112 therebelow to form a first gate G1 and a first gate insulating layer GI1 in the first region R1, a second gate G2 and a second gate insulating layer GI2 in the second region R2, and a third gate G3 and a third gate insulating layer GI3 in third region R3.

In the first region R1, the first gate G1 is formed on a part of the upper portions of the fin portions F exposed by the first isolation structure ST1′, and the first gate insulating layer GI1 is formed between the first gate G1 and the fin portions F.

In the second region R2, the second gate G2 is formed on the substrate 100 and a part of the second isolation structure ST2′, and the dielectric layer 112 between the second gate G2 and the substrate 100 and the second isolation structure ST2′ located below the second gate G2 form the second gate insulating layer GI2.

In addition, a distance D between the sidewall of the second gate G2 on the second isolation structure ST2′ and the substrate 100 on the side of the second isolation structure ST2′ away from the second gate G2 is greater than a thickness H of the second isolation structure ST2′ below the second gate G2.

In the third region R3, the third gate G3 is formed on the substrate 100, and the third gate insulating layer GI3 is formed between the third gate G3 and the substrate 100.

Then, a doped region 116 is formed in the substrate 100 on one side of the second gate G2 away from the drift region 106 as an LDD region. After that, source/drain regions are formed on both sides of the first gate G1, both sides of the second gate G2, and both sides of the third gate G3. In the first region R1, the source/drain regions are formed on or in the fin portions F on both sides of the first gate G1 in the extending direction of the fin portions F (the direction perpendicular to the drawing plane). In the second region R2, the source/drain regions 118 are formed in the substrate 100 on the side of the second gate G2 away from the drift region 106 and in the drift region 106. In the third region R3, the source/drain regions 120 are formed in the substrate 100 on both sides of the third gate G3. In this way, a semiconductor structure 10 of the present embodiment is formed.

In the semiconductor structure 10, the gate insulating layer of the transistor in the second region R2 is composed of the second isolation structure ST2′ with a larger thickness and the dielectric layer 112 with a smaller thickness. Therefore, the source/drain region 118 adjacent to the second isolation structure ST2′ (the source/drain region 118 on the left side in the FIG. 1G) may withstand a high voltage, such as a voltage transmitted to the high-voltage device in the third region R3, while the source/drain region 118 adjacent to the dielectric layer 112 (the source/drain region 118 on the right side in FIG. 1G) may accept a low voltage, such as a voltage from the low-voltage device in the first region R1, so that the transistor in the second region R2 may be used as the EDMOS transistor in a level shifter circuit.

In the transistor in the second region R2, the drift region 106 extends from the bottom of the source/drain region 118 to the bottom of the second isolation structure ST2′ as a portion of the second gate insulating layer GI2, and the boundary BD of the end of the drift region 106 extending below the second isolation structure ST2′ is aligned with or adjacent to the sidewall of the second isolation structure ST2′, so that the length of the channel region between the LDD region (doped region 116) and the drift region 106 may not be too long to avoid high on-resistance (Ron).

In addition, in the transistor in the second region R2, the distance D between the second gate G2 and the substrate 100 is greater than the thickness H of the second gate insulating layer GI2 below the second gate G2 (second isolation structure ST2′), so the short circuit caused by too small distance between the gate and the substrate may be effectively avoided.

Furthermore, during the manufacturing process of the semiconductor structure 10, the process of the transistor used in the level shifter circuit in the second region R2 may be integrated with the process of the FinFET in the first region R1, thus the process steps may be effectively simplified.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a substrate, having a first region, a second region and a third region, wherein the substrate in the first region comprises a plurality of fin portions;
a first isolation structure, disposed around the plurality of fin portions and exposing a portion of each of the plurality of fin portions;
a second isolation structure, disposed in the substrate in the second region;
a first gate, disposed on the exposed portions of the plurality of fin portions;
a first gate insulating layer, disposed between the first gate and the plurality of fin portions;
a second gate, disposed on the substrate in the second region and on a portion of the second isolation structure;
a second gate insulating layer, disposed between the second gate and the substrate;
a drift region, disposed in the substrate on a side of the second isolation structure away from the second gate, and extending below the second isolation structure;
a third gate, disposed on the substrate in the third region;
a third gate insulating layer, disposed between the third gate and the substrate; and
source/drain regions, disposed at the fin portions on both sides of the first gate in an extending direction of each of the plurality of fin portions, in the substrate on both sides of the second gate and in the substrate on both sides of the third gate.

2. The semiconductor structure of claim 1, wherein a top surface of the second isolation structure is lower than a top surface of the first isolation structure.

3. The semiconductor structure of claim 1, wherein a top surface of the second isolation structure is lower than a top surface of the substrate in the second region.

4. The semiconductor structure of claim 3, wherein the second isolation structure has an extension portion on the side away from the second gate, a top surface of the extension portion is coplanar with the top surface of the substrate in the second region, and the extension portion is separated from the second gate.

5. The semiconductor structure of claim 1, wherein a bottom surface of the second isolation structure is coplanar with a bottom surface of the first isolation structure.

6. The semiconductor structure of claim 1, wherein a distance between a sidewall of the second gate located on the second isolation structure and the substrate on the side of the second isolation structure away from the second gate is greater than a thickness of the second isolation structure below the second gate.

7. The semiconductor structure of claim 1, wherein the source/drain region in the second region is located in the drift region.

8. The semiconductor structure of claim 1, wherein a top surface of the substrate in the third region is lower than a top surface of each of the plurality of fin portions.

9. The semiconductor structure of claim 1, wherein a boundary of an end of the drift region below the second isolation structure is aligned with a sidewall of the second isolation structure.

10. A manufacturing method of a semiconductor structure, comprising:
providing a substrate, wherein the substrate has a first region, a second region and a third region, and the substrate in the first region comprises a plurality of fin portions;
forming a first isolation structure around the plurality of fin portions, wherein the first isolation structure exposes a portion of each of the plurality of fin portions;
forming a second isolation structure in the substrate in the second region;
forming a first gate on the exposed portions of the plurality of fin portions;
forming a first gate insulating layer between the first gate and the plurality of fin portions;
forming a second gate on the substrate in the second region and on a portion of the second isolation structure;
forming a second gate insulating layer between the second gate and the substrate;
forming a drift region in the substrate on a side of the second isolation structure away from the second gate, wherein the drift region extends below the second isolation structure;
forming a third gate on the substrate in the third region;
forming a third gate insulating layer between the third gate and the substrate; and
forming source/drain regions at the fin portions on both sides of the first gate in an extending direction of each of the plurality of fin portions, in the substrate on both sides of the second gate and in the substrate on both sides of the third gate.

11. The manufacturing method of claim 10, wherein a forming method of the plurality of fin portions, the first isolation structure and the second isolation structure comprises:
forming a first initial isolation structure in the substrate in the first region to define the plurality of fin portions;
forming a second initial isolation structure in the substrate in the second region;
removing a part of the second initial isolation structure, so that a top surface of the second initial isolation structure is lower than a top surface of the first initial isolation structure;
removing a part of the first initial isolation structure to form the first isolation structure; and
removing a part of the second initial isolation structure to form the second isolation structure.

12. The manufacturing method of claim 11, further comprising removing a part of the substrate in the third region before forming the first initial isolation structure and the second initial structure isolation, so that a top surface of the substrate in the third region is lower than top surfaces of remaining parts of the substrate.

13. The manufacturing method of claim 11, wherein a bottom surface of the second initial isolation structure is coplanar with a bottom surface of the first initial isolation structure.

14. The manufacturing method of claim 11, wherein the drift region is formed in the substrate on a side of the second initial isolation structure after forming the first initial isolation structure and the second initial isolation structure and before removing the part of the second initial isolation structure so that the top surface of the second initial isolation structure is lower than the top surface of the first initial isolation structure.

15. The manufacturing method of claim 11, wherein the third gate insulating layer is formed on the substrate in the third region after removing the part of the second initial isolation structure so that the top surface of the second initial isolation structure is lower than the top surface of the first initial isolation structure and before removing the part of the first initial isolation structure.

16. The manufacturing method of claim 15, wherein the first gate, the first gate insulating layer, the second gate, the second gate insulating layer and the third gate are formed after removing the part of the second initial isolation structure to form the second isolation structure.

17. The manufacturing method of claim 16, wherein the source/drain regions are formed after forming the first gate, the second gate and the third gate.

18. The manufacturing method of claim 10, wherein the second isolation structure has an extension portion on the side away from the second gate, a top surface of the extension portion is coplanar with a top surface of the substrate in the second region, and the extension portion is separated from the second gate.

19. The manufacturing method of claim 10, wherein a distance between a sidewall of the second gate located on the second isolation structure and the substrate on the side of the second isolation structure away from the second gate is greater than a thickness of the second isolation structure below the second gate.

20. The manufacturing method of claim 10, wherein a boundary of an end of the drift region below the second isolation structure is aligned with a sidewall of the second isolation structure.
